(19) United States
(12) Patent Application Publication
(10) Pub. No.: US 2015/0346243 A1
(43) Pub. Date: Dec. 3, 2015

(54) CURRENT LOAD DETECTION DEVICE AND CURRENT LOAD DETECTION METHOD

(71) Applicant: YOKOGAWA ELECTRIC CORPORATION, Tokyo (JP)

(72) Inventor: Koji OTA, Tokyo (JP)

(73) Assignee: YOKOGAWA ELECTRIC CORPORATION, Tokyo (JP)

(21) Appl. No.: 14/721,382

(22) Filed: May 26, 2015

(30) Foreign Application Priority Data
May 27, 2014 (JP) 2014-108657

(51) Int. Cl. G01R 19/00

(52) U.S. Cl. CPC G01R 19/0092

(57) ABSTRACT

A current load detection device is configured to detect a current load to a common power supply unit of a system in which a plurality of devices is connected to the common power supply unit. The current load detection device includes resistances provided for each of the plurality of devices and having resistance values corresponding to consumption current of each of the plurality of devices, a parallel connection unit configured to connect the resistances provided for the plurality of devices in parallel when the plurality of devices is connected to the power supply unit, and a measuring unit configured to measure a combined resistance value of the resistances connected in parallel by the parallel connection unit.

### CROSS-REFERENCE TO RELATED APPLICATION

The present application claims priority from Japanese Patent Application No. 2014-108657 filed on May 27, 2014, the entire content of which is incorporated herein by reference.

### BACKGROUND

The present invention relates to a current load detection device and the like configured to detect a current load to a common power supply unit of a system in which a plurality of devices is connected to the common power supply unit.

In a system in which a plurality of devices is connected to a common power supply unit, since it is necessary not to exceed a rated output of the power supply unit, following methods are adopted, for example.

(1) The number of slots to which the devices are mounted is limited in advance so as to limit the number of the devices mountable to the power supply unit.

(2) The limitations on the number and types of the devices connectable to the power supply unit are described in an operating manual and the like.

(3) The number and types of the devices actually connected to the power supply unit are detected by software.

[Patent Document 1] Japanese Patent Application Publication No. 2010-128804A

However, according to the method (1), it is not possible to cope with a change in the specification for the future. Also, when the power consumption and the like are different depending on the devices, it is not possible to control a total sum of the power consumptions only with the number of the devices.

According to the method (2), since there is a possibility that a device exceeding the limitations will be erroneously connected, it is necessary to add an overcurrent limiting circuit to the power supply unit. However, in order to increase detection precision of the overcurrent, the loss of the power occurs or the cost increases and a mounting area is enlarged. Also, the power being used may be varied even in the same device, depending on using conditions. Therefore, even though a problem is not caused at the start of the operation, the load current may increase during the operation, so that the overcurrent limiting circuit may operate. Normally, this situation should be avoided before the operation starts.

The method (3) has reality when the software is installed in an upper system. However, if the corresponding system is not provided, processing that is executed when the device is connected at a hot line condition is complicated. Also, when there is a plurality of types of the power supply unit, it is also necessary to detect the types of the power supply unit.

### SUMMARY

Exemplary embodiments of the invention provide a current load detection device and the like capable of securely avoiding occurrence of an excessive load to a power supply unit just by adding a simple circuit.

A current load detection device configured to detect a current load to a common power supply unit of a system in which a plurality of devices is connected to the common power supply unit, according to an exemplary embodiment of the invention, the current load detection device comprises:

resistances provided for each of the plurality of devices and having resistance values corresponding to consumption current of each of the plurality of devices;

a parallel connection unit configured to connect the resistances provided for the plurality of devices in parallel when the plurality of devices is connected to the power supply unit; and

a measuring unit configured to measure a combined resistance value of the resistances connected in parallel by the parallel connection unit.

According to the current load detection device, when the plurality of devices is connected to the power supply unit, the resistances provided for the plurality of devices are connected in parallel and the combined resistance value of the resistances connected in parallel is measured. Therefore, it is possible to securely avoid occurrence of an excessive load to the power supply unit just by adding a simple circuit.

The resistance values of the resistances may be configured to be inversely proportional to consumption current values of the devices for which the resistances are provided.

The current load detection device may further comprise:

a reset signal output unit configured to output a reset signal for prohibiting operations of the plurality of devices when the combined resistance value of the resistances measured by the measuring unit is smaller than a threshold value.

The current load detection device may further comprise:

a display unit configured to, when the combined resistance value of the resistances measured by the measuring unit is smaller than a threshold value, display the corresponding fact.

A current load detection method of detecting a current load to a common power supply unit of a system in which a plurality of devices is connected to the common power supply unit, according to an exemplary embodiment of the invention, the current load detection method comprises:

providing the plurality of devices in advance with resistances having resistance values corresponding to consumption current of each of the plurality of devices;

connecting the plurality of devices to the power supply unit to connect the resistances provided for the plurality of devices in parallel; and

measuring a combined resistance value of the resistances connected in parallel.

According to the current load detection method, when the plurality of devices is connected to the power supply unit, the resistances provided for the plurality of devices are connected in parallel and the combined resistance value of the resistances connected in parallel is measured. Therefore, it is possible to securely avoid occurrence of an excessive load to the power supply unit just by adding a simple circuit.

The resistance values of the resistances may be configured to be inversely proportional to consumption current values of the devices for which the resistances are provided.

According to the current load detection device, when the plurality of devices is connected to the power supply unit, the resistances provided for the plurality of devices are connected in parallel and the combined resistance value of the resistances connected in parallel is measured. Therefore, it is possible to securely avoid occurrence of an excessive load to the power supply unit just by adding a simple circuit.

Also, according to the current load detection method, when the plurality of devices is connected to the power supply unit, the resistances provided for the plurality of devices are connected in parallel and the combined resistance value of the resistances connected in parallel is measured. Therefore, it is possible to securely avoid occurrence of an excessive load to the power supply unit just by adding a simple circuit.

### BRIEF DESCRIPTION OF THE DRAWINGS

FIG. 1A illustrates a method of connecting module devices and a power supply unit in a state before the module devices are connected to the power supply unit and FIG. 1B illustrates a state where the module devices are connected to the power supply unit.

FIG. 2 is a circuit diagram of elements provided for the power supply unit and module devices relating to a current load detection device.

FIG. 3 shows a connection state of resistances.

FIG. 4 shows a configuration example of displaying an output of a comparator.

FIG. 5 illustrates another example of the method of connecting the module devices and the power supply unit.

### DETAILED DESCRIPTION

Hereinafter, an exemplary embodiment of a current load detection device of the present invention will be described.

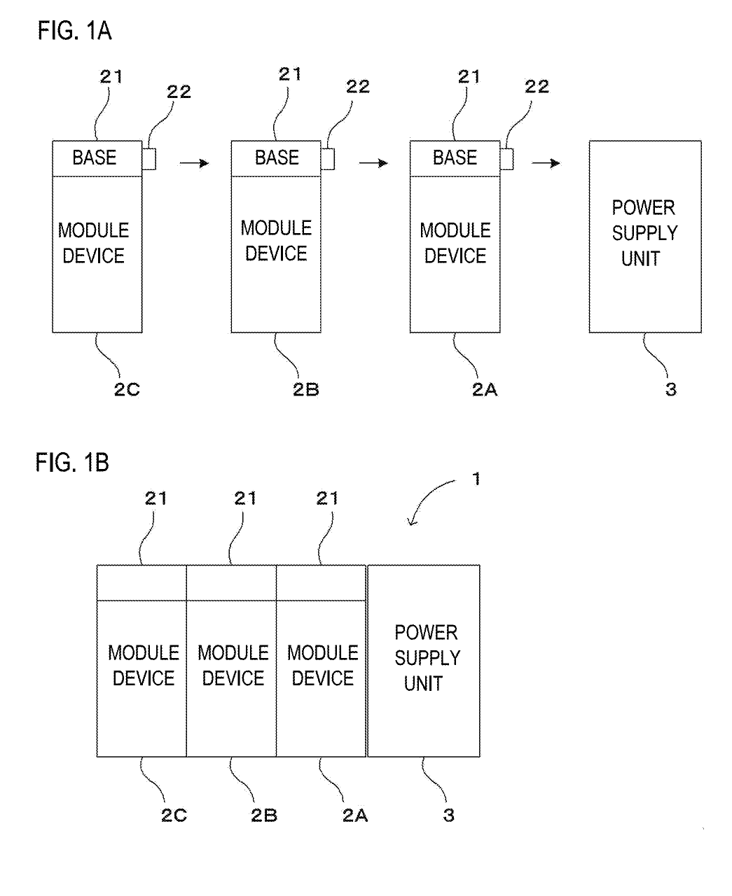

FIGS. 1A and 1B illustrate a method of connecting module devices 2A, 2B, 2C and a power supply unit 3, which configure a current load detection device 1 of this exemplary embodiment. FIG. 1A illustrates a state before the module devices 2A, 2B, 2C are connected to the power supply unit 3, and FIG. 1B illustrates a state where the module devices 2A, 2B, 2C are connected to the power supply unit 3.

As shown in FIG. 1A, a common base 21 (parallel connection unit) is detachably attached to each of the module devices 2A, 2B, 2C, and a connection part 22 provided for the base 21 is fitted to the adjacent power supply unit 3 or the base 21 of the adjacent module device, so that the module devices 2A, 2B, 2C can be connected to the power supply unit 3. At this state, the module devices 2A, 2B, 2C can be fed with power from the power supply unit 3 through the bases 21. The power supply unit 3 is configured to be fed with power from a commercial power supply and the like and to generate a desired supply voltage.

In the meantime, the three module devices are shown in FIG. 1A. However, the number of the module devices to be connected to the power supply unit is not limited in structure.

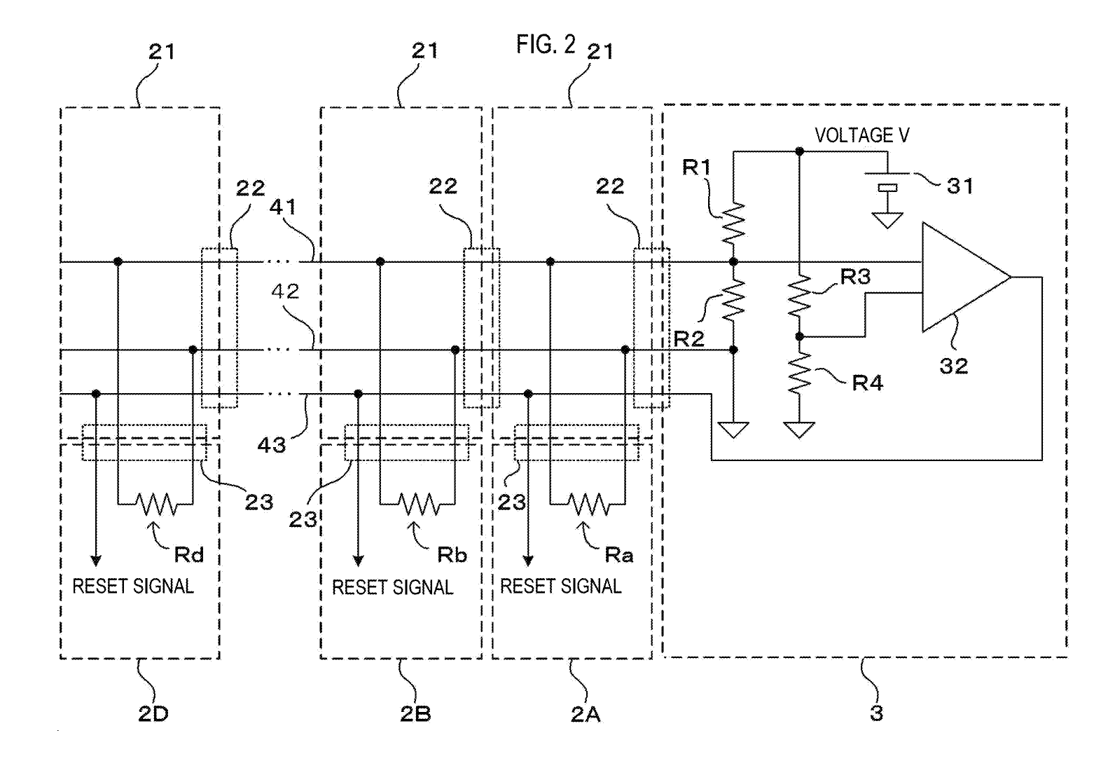

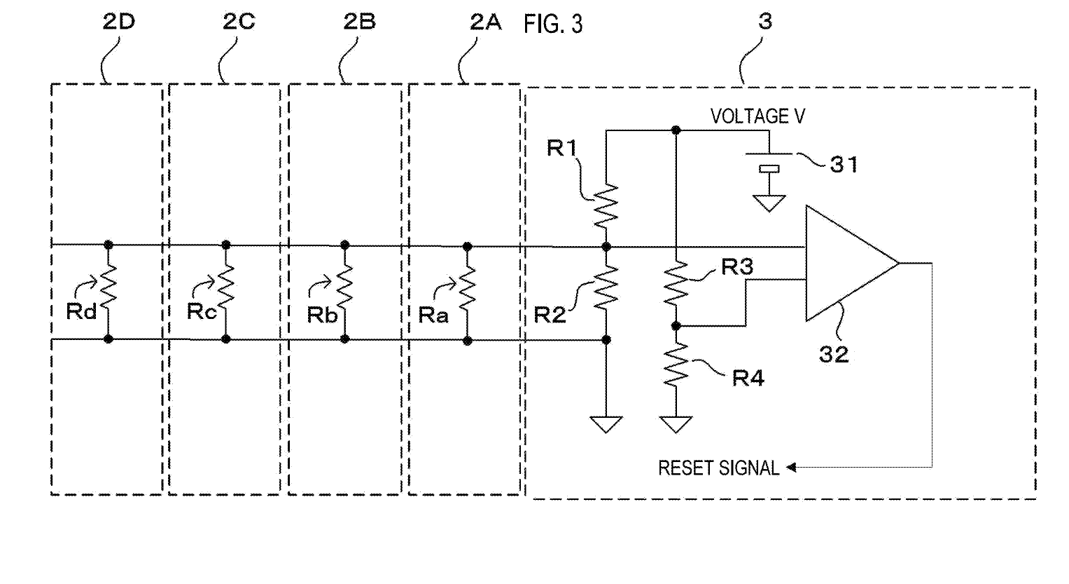

FIG. 2 is a circuit diagram of elements provided for the power supply unit 3 and module devices 2A, 2B, 2C relating to the current load detection device. FIG. 3 shows a connection state of resistances. FIGS. 2 and 3 show an example in which four module devices 2A, 2B, 2C, 2D are connected to the power supply unit 3.

As shown in FIGS. 2 and 3, the module devices 2A, 2B, 2C, 2D are provided with resistances Ra, Rb, Rc, Rd, respectively.

As shown in FIGS. 2 and 3, the power supply unit 3 is provided with a voltage source 31 (measuring unit) and a comparator 32 (reset signal output unit, measuring unit, display unit). In the meantime, the voltage source 31 may be common to a power feeding source to the module devices 2A, 2B, 2C, 2D or may be independent of the power feeding source.

Also, resistances R1, R2 and resistances R3, R4 (measuring unit) are respectively connected in series between the voltage source 31 and the ground. A connection point of the resistances R1, R2 and a connection point of the resistances R3, R4 are connected to input terminals of the comparator 32, so that voltages of both connection points are compared.

Further, as shown in FIG. 2, the connection point of the resistances R1, R2 is connected to signal lines 41 of the bases 21, 21, . . . through the connection parts 22, 22, . . . , and the ground of the power supply unit 3 is connected to signal lines 42 of the bases 21, 21, . . . through the connection parts 22, 22, . . . .

Also, an output terminal of the comparator 32 is connected to signal lines 43 of the bases 21, 21, . . . through the connection parts 22, 22, . . . , and the signal lines 43 are connected to the module devices 2A, 2B, 2C, 2D through connection parts 23, 23, . . . .

In the meantime, both ends of the resistances Ra, Rb, Rc, Rd of the module devices 2A, 2B, 2C, 2D are respectively connected to the signal lines 41 and the signal lines 42 through the connection parts 23, 23, . . . for connecting the bases 21 to the module devices 2A, 2B, 2C, 2D. Therefore, the resistances Ra, Rb, Rc, Rd and the resistance R2 are connected in parallel with each other.

In this exemplary embodiment, resistance values of the resistances Ra, Rb, Rc, Rd are set to be inversely proportional to power consumptions (consumption currents) of the module devices 2A, 2B, 2C, 2D, respectively. For example, when the power consumption of the module device is 0.5 W, the resistance of 10 kΩ is preferably used, and when the power consumption of the module device is 1 W, the resistance of 5 kΩ is preferably used, and when the power consumption of the module device is 2.5 W, the resistance of 2 kΩ is preferably used.

In this exemplary embodiment, since the resistance values of the resistances Ra, Rb, Rc, Rd are set to be inversely proportional to the power consumptions (consumption currents) of the module devices 2A, 2B, 2C, 2D, respectively, a combined resistance resulting from the parallel connection of the resistances Ra, Rb, Rc, Rd is inversely proportional to a total sum of the power consumptions (consumption currents). Therefore, in theory, it is possible to calculate the power consumption (consumption current) by calculating the combined resistance.

For example, when values of the resistance R1 and the resistance R3 of the power supply unit 3 are made to be the same (for example, 1 kΩ, a value of the resistance R4 of the power supply unit 3 is set to a resistance of a value resulting from a parallel connection of the resistance R2 and a resistance having a value inversely proportional to rated output power (rated output current). For example, in case that the rated output is 5 W, a resistance of 2 kΩ is connected in parallel with a resistance of the same value as the resistance R2 and is used as the resistance R4, and in case that the rated output is 10 W, a resistance of 1 kΩ is connected in parallel with a resistance of the same value as the resistance R2 and is used as the resistance R4. At this time, the output of the comparator 32 indicates a magnitude relation between the power consumptions (consumption currents) of the module devices 2A, 2B, 2C, 2D and the rated output (rated current) of the power supply unit 3. Therefore, when the power consumptions (consumption currents) of the module devices 2A, 2B, 2C, 2D are greater than the rated output (rated current) of the power supply unit 3, which is a threshold value, a reset signal is output from the comparator 32 and is applied to the module devices 2A, 2B, 2C, 2D, so that operations thereof can be prohibited. Accordingly, it is possible to prevent the total load current from exceeding the rated current.

In the meantime, in general, the module device does not consume the power so much when the power is simply fed to the module device, and when the module device actually starts to operate, the load current increases. Also, there is a device of which load current increases at a specific condition such as driving of a relay. Therefore, when the resistance values of the resistances Ra, Rb, Rc, Rd are set to resistance values corresponding to maximum power consumptions or maximum load currents of the respective devices, the maximum load current information is provided to the power supply unit 3 before an operation actually starts. Thereby, when there is a possibility that the maximum load current will exceed the rated output current of the power supply unit 3, the operation of the corresponding device is not activated.

In general, the power supply unit is provided with an overcurrent limiting circuit. However, when the current load detection device of this exemplary embodiment is used, the operation activation is appropriately prohibited. Therefore, it doesn't matter if the detection precision of the output current by the overcurrent limiting circuit is low, and only an output short fault may be supposed, for example.

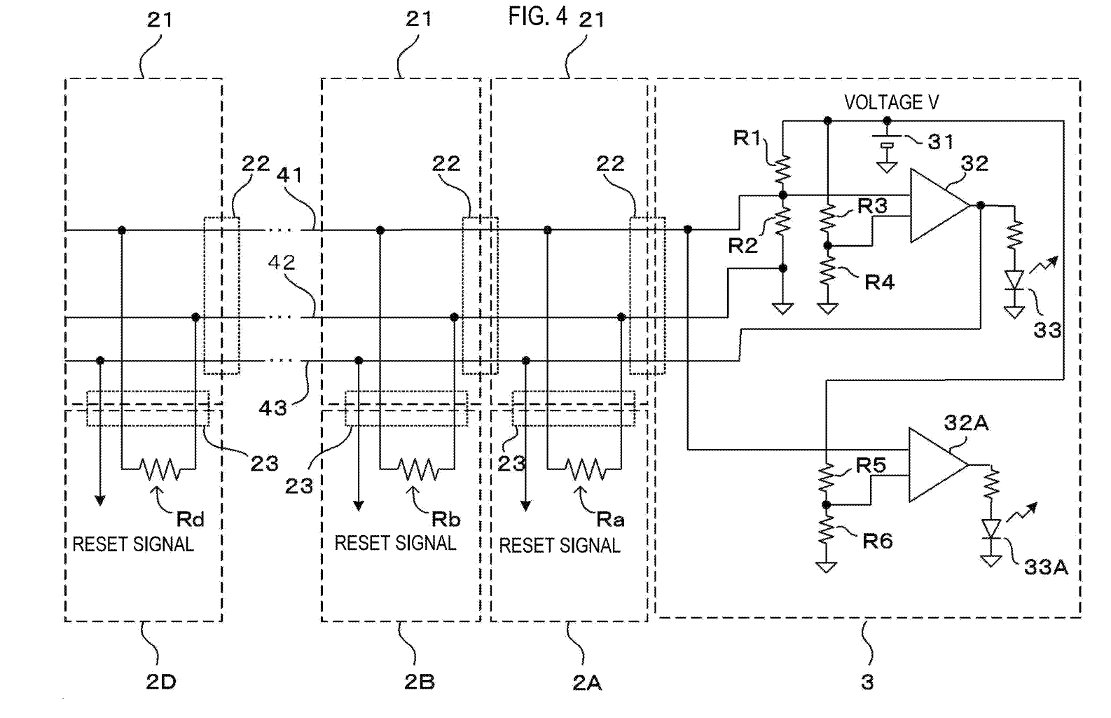

FIG. 4 shows a configuration example for displaying the output of the comparator 32.

As shown in FIG. 4, in the configuration, a circuit 33 configured to turn on an LED by the output of the comparator 32 is added. Thereby, it is possible to display whether a reset signal is output or not by turning on the LED.

Also, in the example of FIG. 4, a comparator 32A (measuring unit, display unit) different from the comparator 32 is additional provided for the power supply unit 3, and a comparison threshold value of the comparator 32A is set by a combination of resistances R5, R6 (measuring unit) of which a combination of values is different from the resistances R3, R4. Also, a circuit 33A configured to turn on an LED by an output of the comparator 32A is added. Thereby, it is possible to display a result of comparison, which is made by the threshold value different from the reference for determining whether the reset signal is output, by turning on the LED. For example, when the power consumption (consumption current) is equal to or greater than a predetermined percentage (for example, 80%) of the rated output power (rated output current), it is possible to display the corresponding relation.

In the meantime, it may be possible to display the relation between the power consumption (consumption current) and the rated output (rated output current) and the like in more detail by increasing the number of the threshold values.

Also, it may be possible to display the relation between the power consumption (consumption current) and the rated output (rated output current) and the like by numerical values, based on a measured value of the combined resistance value of the resistances connected in parallel, without being limited to the detection or display using the threshold value. As a method of measuring or assessing the combined resistance value of the resistances connected in parallel, a method based on the Ohm's law may be widely applied.

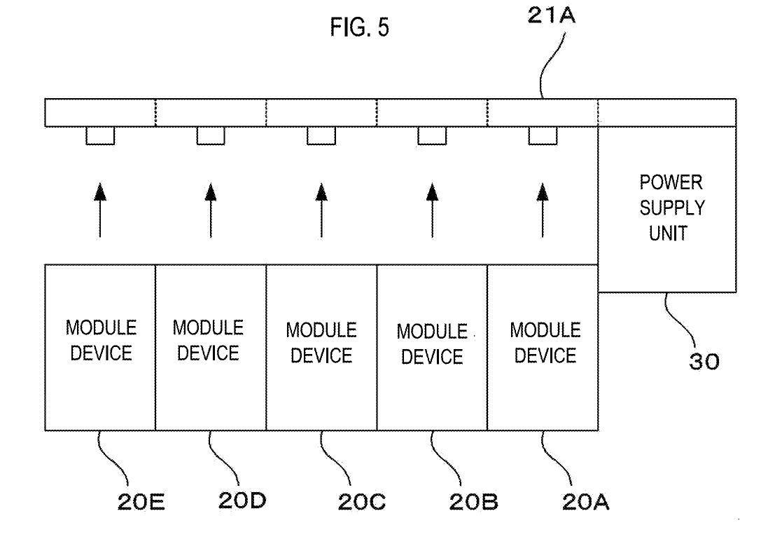

FIG. 5 illustrates another example of the method of connecting the module devices and the power supply unit.

In the example of FIG. 5, the number of module devices 20A to 20E that can be connected to a power supply unit 30 through a base unit 21A is limited in advance. However, the present invention can also be applied to the corresponding configuration.

As described above, according to the current load detection device and current load detection method of the present invention, the current load to the power supply unit is detected on the basis of the combined resistance value of the resistances connected in parallel. Therefore, it is possible to securely avoid occurrence of an excessive load to the power supply unit just by adding the simple circuit without requiring the complicated processing.

The present invention is not limited to the above exemplary embodiment. The present invention can be widely applied to a current load detection device configured to detect a current load to a common power supply unit of a system in which a plurality of devices is connected to the common power supply unit.

What is claimed is:

1. A current load detection device configured to detect a current load to a common power supply unit of a system in which a plurality of devices is connected to the common power supply unit, the current load detection device comprising:
resistances provided for each of the plurality of devices and having resistance values corresponding to consumption current of each of the plurality of devices;
a parallel connection unit configured to connect the resistances provided for the plurality of devices in parallel when the plurality of devices is connected to the power supply unit; and
a measuring unit configured to measure a combined resistance value of the resistances connected in parallel by the parallel connection unit.

2. The current load detection device according to claim 1, wherein the resistance values of the resistances are configured to be inversely proportional to consumption current values of the devices for which the resistances are provided.

3. The current load detection device according to claim 1, further comprising:
a reset signal output unit configured to output a reset signal for prohibiting operations of the plurality of devices when the combined resistance value of the resistances measured by the measuring unit is smaller than a threshold value.

4. The current load detection device according to claim 1, further comprising:
a display unit configured to, when the combined resistance value of the resistances measured by the measuring unit is smaller than a threshold value, display the corresponding fact.

5. A current load detection method of detecting a current load to a common power supply unit of a system in which a plurality of devices is connected to the common power supply unit, the current load detection method comprising:
providing the plurality of devices in advance with resistances having resistance values corresponding to consumption current of each of the plurality of devices;
connecting the plurality of devices to the power supply unit to connect the resistances provided for the plurality of devices in parallel; and
measuring a combined resistance value of the resistances connected in parallel.

6. The current load detection method according to claim 5, wherein the resistance values of the resistances are configured to be inversely proportional to consumption current values of the devices for which the resistances are provided.
